(19) United States
(12) Patent Application Publication
(10) Pub. No.: US 2026/0288284 A1
(43) Pub. Date: Sep. 24, 2026

(54) TOUCH SCREEN PANEL AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Jun YAN, Beijing (CN); Xiangdan DONG, Beijing (CN); Yu WANG, Beijing (CN); Kemeng TONG, Beijing (CN); Yi HE, Beijing (CN); Ting LI, Beijing (CN)

(21) Appl. No.: 19/479,729

(22) PCT Filed: Jan. 15, 2025
(86) PCT No.: PCT/CN2025/072570

§ 371 Date: Oct. 28, 2025

(30) Foreign Application Priority Data
Feb. 26, 2024 (CN) 202410211650.4

(51) Int. Cl. G06F 3/044; H10K 59/122; H10K 59/40; H10K 59/80; H10K 102/00

(52) U.S. Cl. CPC G06F 3/0445; G06F 3/0442; G06F 3/0446; H10K 59/122; H10K 59/40; H10K 59/873; G06F 2203/04112; H10K 2102/351

(57) ABSTRACT

A touch display panel and a display apparatus are disclosed. The touch display panel includes: a display substrate; and a touch-control layer, located at a display side of the display substrate and including a plurality of touch conductive layers, where one touch conductive layer of the touch conductive layers includes a metal grid structure formed by interweaving a plurality of metal lines; and a line width h1 of one metal line of the metal lines and a size h2 of the touch display panel satisfy h1>2.5, 1.5≤h2/h1≤3.6, a unit of the line width h1 of the metal line is micrometer, and a unit of the size h2 of the touch display panel is inch.

### CROSS-REFERENCE TO RELATED APPLICATION

The present disclosure is a National Stage of International Application No. PCT/CN2025/072570, filed on Jan. 15, 2025, which claims priority to Chinese Patent Applications No. 202410211650.4, filed with the China National Intellectual Property Administration on Feb. 26, 2024, and entitled “Touch screen Panel and Display Apparatus”, the content of which is hereby incorporated by reference in its entirety.

### TECHNICAL FIELD

The present disclosure relates to the technical field of display, and particularly to a touch display panel and a display apparatus.

### BACKGROUND

With the development of active stylus technology, more and more touch screens, for example, mobile phones, laptops, tablets and other electronic products with touch screens are equipped with the active stylus, resulting in higher requirements for the performance of the active stylus. However, Resistor-Capacitance (RC) Loading of a medium and large size touch screen is large, and signal attenuation is serious when the active stylus is used for touch control, affecting touch control performance.

### SUMMARY

Embodiments of the present disclosure provide a touch display panel and a display apparatus, to reduce signal attenuation.

Embodiments of the present disclosure provide a touch display panel, including:
a display substrate; and
a touch layer, located at a display side of the display substrate and including a plurality of touch conductive layers; where one touch conductive layer of the touch conductive layers includes a metal grid structure formed by interweaving a plurality of metal lines; where a line width h1 of one metal line of the metal lines and a size h2 of the touch display panel satisfy h1>2.5, 1.5≤h2/h1≤3.6, a unit of the line width h1 of the metal line is micrometer, and a unit of the size h2 of the touch display panel is inch.

In some embodiments, the size of the touch display panel is less than 10 inches, and the line width of the metal line is less than or equal to 4 micrometers.

In some embodiments, the size of the touch display panel is greater than or equal to 10 inches, and the line width of the metal line is greater than or equal to 5 micrometers and less than or equal to 6.5 micrometers.

In some embodiments, the plurality of touch conductive layers include a first touch conductive layer and a second touch conductive layer at a side of the first touch conductive layer away from an encapsulation layer; the touch layer further includes a touch insulating layer located between the first touch conductive layer and the second touch conductive layer;
a thickness of the first touch conductive layer is greater than or equal to 0.34 micrometers, and a thickness of the second touch conductive layer is greater than or equal to 0.42 micrometers.

In some embodiments, the touch insulating layer is an inorganic touch insulating layer;
the thickness of the first touch conductive layer is less than or equal to 0.42 micrometers, a thickness of the inorganic touch insulating layer is greater than or equal to 0.35 micrometers and less than or equal to 0.43 micrometers, and the thickness of the second touch conductive layer is less than or equal to 0.5 micrometer.

In some embodiments, the touch insulating layer is an organic touch insulating layer;
the thickness of the first touch conductive layer is less than or equal to 0.72 micrometers, a thickness of the organic touch insulating layer is greater than or equal to 1.4 micrometers and less than or equal to 1.8 micrometers, and the thickness of the second touch conductive layer is less than or equal to 0.72 micrometers.

In some embodiments, the thickness of the first touch conductive layer is equal to the thickness of the second touch conductive layer.

In some embodiments, the touch display panel includes a display region and a peripheral region surrounding the display region; the display substrate includes:
a base substrate;
a pixel defining layer, located at a side of the base substrate and including a plurality of opening regions; and
an encapsulation layer, including at least one organic encapsulation layer at a side of the pixel defining layer away from the base substrate; where in the display region, a difference between a minimum thickness of the organic encapsulation layer included in the encapsulation layer in a direction perpendicular to the base substrate and the size h2 of the touch display panel is greater than or equal to 1 micrometer; where in the display region, the minimum thickness of the organic encapsulation layer included in the encapsulation layer in the direction perpendicular to the base substrate is a thickness of the organic encapsulation layer corresponding to a position where the pixel defining layer is located in the direction perpendicular to the base substrate.

In some embodiments, the size of the touch display panel is greater than 10 inches; the encapsulation layer further includes: a first inorganic encapsulation layer, and a second inorganic encapsulation layer located at a side of the first inorganic encapsulation layer away from the base substrate; the at least one organic encapsulation layer includes: a first inorganic encapsulation layer located between the first inorganic encapsulation layer and the second inorganic encapsulation layer;

in the display region, a minimum thickness h3 of the first organic encapsulating layer in the direction perpendicular to the base substrate is greater than or equal to 14 micrometers and less than or equal to 18 micrometers.

In some embodiments, in the display region, a difference between the minimum thickness h3 of the first organic encapsulation layer in the direction perpendicular to the base substrate and the size h2 of the touch display panel is equal to 1 micrometer.

In some embodiments, the encapsulation layer further includes: a first inorganic encapsulation layer, and a second inorganic encapsulation layer located at a side of the first inorganic encapsulation layer away from the base substrate; the at least one organic encapsulation layer includes: a first inorganic encapsulation layer located between the first inorganic encapsulation layer and the second inorganic encapsulation layer, and a second inorganic encapsulation layer located at a side of the second inorganic encapsulation layer away from the first organic encapsulation layer.

In some embodiments, a minimum thickness of the second organic encapsulation layer in the display region is less than a minimum thickness of the first organic encapsulation layer in the display region.

In some embodiments, the size of the touch display panel is greater than 10 inches; the minimum thickness of the first organic encapsulating layer in the display region is greater than or equal to 12 micrometers and less than or equal to 18 micrometers, the minimum thickness of the second organic encapsulating layer in the display region is greater than or equal to 8 micrometers and less than or equal to 14 micrometers.

Embodiments of the present disclosure provide a touch display panel, including a display region and a peripheral region surrounding the display region; where the touch display panel includes:
a display substrate, including a base substrate, a pixel defining layer and an encapsulation layer, where the pixel defining layer and the encapsulation layer are located at a side of the base substrate; the pixel defining layer includes a plurality of opening regions, the encapsulation layer includes at least one organic encapsulation layer at a side of the pixel defining layer away from the base substrate; in the display region, a difference between a minimum thickness of the organic encapsulation layer included in the encapsulation layer in a direction perpendicular to the base substrate and a size h2 of the touch display panel is greater than or equal to 1 micrometer; where in the display region, the minimum thickness of the organic encapsulation layer included in the encapsulation layer in the direction perpendicular to the base substrate is a thickness of the organic encapsulation layer corresponding to a position where the pixel defining layer is located in the direction perpendicular to the base substrate; and
a touch layer, located at a display side of the display substrate.

In some embodiments, the size of the touch display panel is greater than 10 inches; the encapsulation layer further includes a first inorganic encapsulation layer, and a second inorganic encapsulation layer located at a side of the first inorganic encapsulation layer away from the base substrate; the at least one organic encapsulation layer includes: a first inorganic encapsulation layer located between the first inorganic encapsulation layer and the second inorganic encapsulation layer;

in the display region, a minimum thickness h3 of the first organic encapsulating layer in the direction perpendicular to the base substrate is greater than or equal to 14 micrometers and less than or equal to 18 micrometers.

In some embodiments, in the display region, a difference between the minimum thickness h3 of the first organic encapsulation layer in the direction perpendicular to the base substrate and the size h2 of the touch display panel is equal to 1 micrometer.

In some embodiments, the encapsulation layer further includes: a first inorganic encapsulation layer, and a second inorganic encapsulation layer located at a side of the first inorganic encapsulation layer away from the base substrate; the at least one organic encapsulation layer includes: a first inorganic encapsulation layer located between the first inorganic encapsulation layer and the second inorganic encapsulation layer, and a second inorganic encapsulation layer located at a side of the second inorganic encapsulation layer away from the first organic encapsulation layer.

In some embodiments, a minimum thickness of the second organic encapsulation layer in the display region is less than a minimum thickness of the first organic encapsulation layer in the display region.

In some embodiments, the size of the touch display panel is greater than 10 inches; the minimum thickness of the first organic encapsulating layer in the display region is greater than or equal to 12 micrometers and less than or equal to 18 micrometers, the minimum thickness of the second organic encapsulating layer in the display region is greater than or equal to 8 micrometers and less than or equal to 14 micrometers.

Embodiments of the present disclosure provide a display apparatus, including the touch display panel according to embodiments of the present disclosure.

For the touch display panel according to an embodiment of the present disclosure, in a case of h1>2.5, the line width h1 of the metal line included in the touch layer and the size h2 of the touch display panel satisfy 1.5≤h2/h1≤3.6. The larger the size h2 of the touch display panel is, the larger the line width h1 of the metal line is. Therefore, with the increase of the size of the touch display panel, the resistance of the touch conductive layer is reduced by correspondingly increasing the line width of the metal line, reducing the RC Loading. Then the signal attenuation is reduced when using the active stylus for touch control, to improve the signal-to-noise ratio, Hover touch, linearity and accuracy of the active stylus. In addition, h2/h1≤3.6 prevents the increase in the line width from failing to satisfy the RC Loading required for the size of the touch display panel in the case where h2/h1 exceeds 3.6. 1.5≤h2/h1 can prevent the metal line from being too wide to shield an opening region of the display substrate, and prevent a light-emitting rate of the touch display panel from being affected.

### BRIEF DESCRIPTION OF FIGURES

In order to illustrate technical solutions in embodiments of the present disclosure more clearly, accompanying drawings that need to be used in describing embodiments will be introduced below briefly. Obviously, the accompanying drawings described below are only some embodiments of the present disclosure, and other accompanying drawings can also be obtained by those ordinary skilled in the art according to these accompanying drawings without creative labor.

FIG. 1 is a schematic diagram of touch control using an active stylus according to an embodiment of the present disclosure;

FIG. 2 is a schematic structural diagram of a touch display panel according to an embodiment of the present disclosure;

FIG. 3 is a sectional view taken along CC′ in FIG. 2 according to an embodiment of the present disclosure;

FIG. 4 is a schematic structural diagram of another touch display panel according to an embodiment of the present disclosure;

FIG. 5 is a schematic structural diagram of another touch display panel according to an embodiment of the present disclosure;

FIG. 6 is a schematic structural diagram of another touch display panel according to an embodiment of the present disclosure;

FIG. 7 is a schematic structural diagram of another touch display panel according to an embodiment of the present disclosure;

FIG. 8 is a sectional view taken along EE′ in FIG. 2 according to an embodiment of the present disclosure;

FIG. 9 is a sectional view taken along FF′ in FIG. 2 according to an embodiment of the present disclosure;

FIG. 10 is another sectional view taken along EE′ in FIG. 2 according to an embodiment of the present disclosure;

FIG. 11 is another sectional view taken along FF′ in FIG. 2 according to an embodiment of the present disclosure;

FIG. 12 is a display noise model according to an embodiment of the present disclosure;

FIG. 13 is a waveform diagram of a cathode and a data signal according to an embodiment of the present disclosure;

FIG. 14 is a schematic structural diagram of another touch display panel according to an embodiment of the present disclosure;

FIG. 15 is a schematic structural diagram of another touch display panel according to an embodiment of the present disclosure;

FIG. 16 is a schematic structural diagram of another touch display panel according to an embodiment of the present disclosure;

FIG. 17 is a schematic diagram of performing touch control on a touch display panel by using an active stylus according to an embodiment of the present disclosure.

### DETAILED DESCRIPTION

For making objectives, technical solutions and advantages of embodiments of the present disclosure clearer, technical solutions of embodiments of the present disclosure will be clearly and completely described below in conjunction with accompanying drawings in embodiments of the present disclosure. Apparently, embodiments described are some rather than all of embodiments of the present disclosure. Embodiments in the present disclosure and features of embodiments may be combined with each other without conflict. Based on embodiments of the present disclosure, all other embodiments obtained by those of ordinary skill in the art without making creative efforts fall within the scope of protection of the present disclosure.

Unless otherwise defined, technical or scientific terms used in the present disclosure should have ordinary meanings as understood by those of ordinary skill in the art to which the present disclosure belongs. The words “first”, “second”, etc. used in the present disclosure do not indicate any order, quantity or importance, but are only used to distinguish different components. The word “including” or “comprising”, etc. indicates that elements or objects before the word include elements or objects after the word and their equivalents, without excluding other elements or objects. The word “connection” or “link”, etc. is not limited to physical or mechanical connections, but may include electrical connections, whether direct or indirect.

It should be noted that a size and a shape of each figure in the drawings do not reflect a true scale, but only for illustrating the present disclosure. Throughout the drawings, identical or similar reference numerals denote identical or similar elements or elements having identical or similar functions.

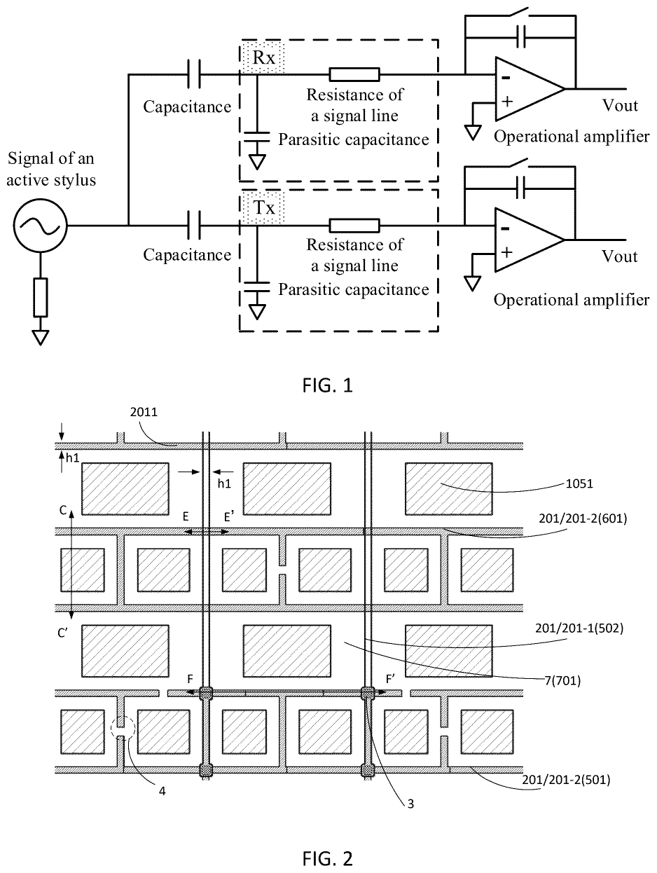

In related art, a schematic diagram of touch control using an active stylus is shown in FIG. 1. A signal of the active stylus is transmitted through a coupling capacitance between the stylus and a Tx electrode and a Rx electrode of a touch screen, passes through RC loading of the touch screen, and is output after reaching an operational amplifier of a driving chip (IC). For the product of Flexible Multi Layer On Cell (FMLOC) technology, the Tx electrode and the Rx electrode are integrated above a display encapsulation layer, with the increase of the screen body, the resistance and capacitance of the Tx electrode and the Rx electrode channel are also increased, the impedance of the Tx electrode and the Rx electrode is increased, and the RC Loading is increased. As a result, the signal attenuation of the active stylus increases, which seriously hinders the application of the active stylus in medium and large size touch products.

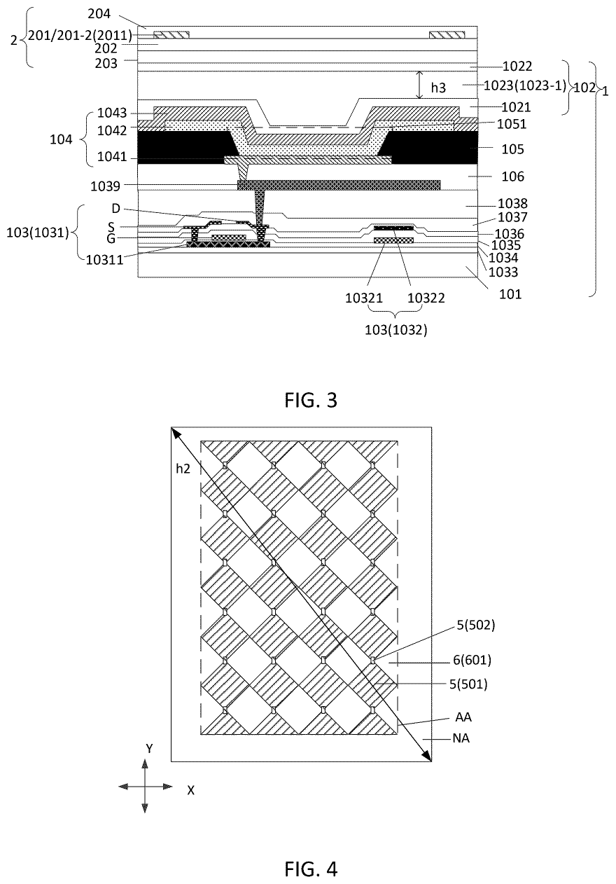

In view of this, embodiments of the present disclosure provide a touch display panel. As shown in FIG. 2, FIG. 3, and FIG. 4, the touch display panel includes:
a display substrate 1; and
a touch layer 2, located at a display side of the display substrate 1 and including a plurality of touch conductive layers 201. One touch conductive layer of the touch conductive layers 201 includes a metal grid structure 7 formed by interweaving a plurality of metal lines 2011. A line width h1 of one metal line of the metal lines 2011 and a size h2 of the touch display panel satisfy h12.5, 1.5≤h2/h1≤3.6. A unit of the line width h1 of the metal line 2011 is micrometer, and a unit of the size h2 of the touch display panel is inch.

The touch display panel according to an embodiment of the present disclosure can be applied to a touch product that uses an active stylus for touch control.

For the touch display panel according to an embodiment of the present disclosure, in a case of h1>2.5, the line width h1 of the metal line included in the touch layer and the size h2 of the touch display panel satisfy 1.5≤h2/h1≤3.6. The larger the size h2 of the touch display panel is, the larger the line width h1 of the metal line is. Therefore, with the increase of the size of the touch display panel, the resistance of the touch conductive layer is reduced by correspondingly increasing the line width of the metal line, reducing the RC Loading. Then the signal attenuation is reduced when using the active stylus for touch control, to improve the signal-to-noise ratio, Hover touch, linearity and accuracy of the active stylus. In addition, h2/h1≤3.6 prevents the increase in the line width from failing to satisfy the RC Loading required for the size of the touch display panel in the case where h2/h1 exceeds 3.6. 1.5≤h2/h1 can prevent the metal line from being too wide to shield an opening region of the display substrate, and prevent a light-emitting rate of the touch display panel from being affected.

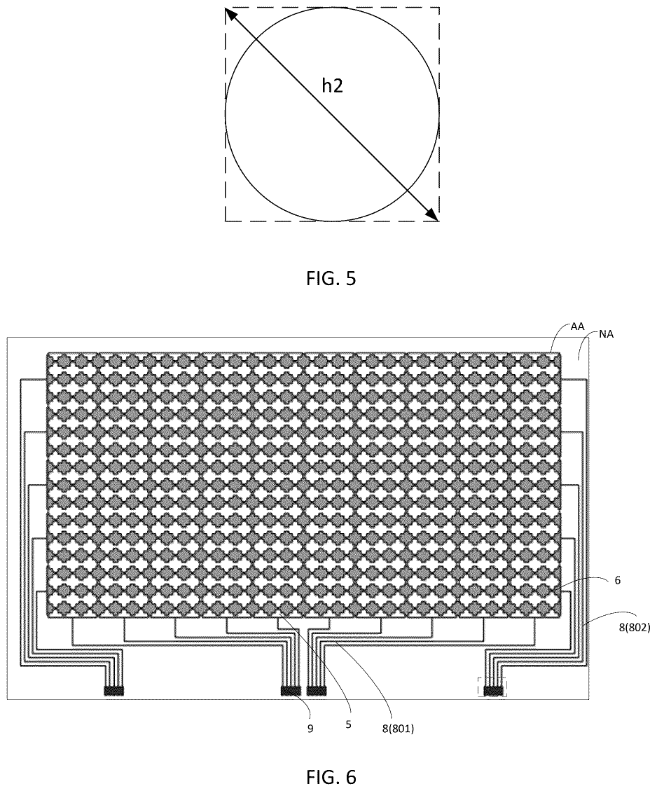

It should be noted that for a rectangular or approximately rectangular touch display panel, as shown in FIG. 4, the size h2 of the touch display panel refers to a length of a diagonal of a rectangle. For a circular or other special-shaped touch display panel, taking a circular shape as an example, as shown in FIG. 5, the size h2 of the touch display panel is a length of a smallest diagonal of a rectangle into which the touch display panel can fall.

It should be noted that FIG. 3 is a sectional view taken along CC′ in FIG. 2.

In some embodiments, in a display region AA, a plurality of touch conductive layers include a plurality of touch electrodes. As shown in FIG. 4, the plurality of touch electrodes include a plurality of first touch electrodes 5 and a plurality of second touch electrodes 6.

The plurality of first touch electrodes 5 are arranged along a first direction X and extend along a second direction Y. One first touch electrode of the first touch electrodes 5 includes a plurality of first sub-electrodes 501 arranged along the second direction Y, and a bridging electrode 502 electrically connecting two adjacent first sub-electrodes 501.

The plurality of second touch electrodes 6 extend along the first direction X and are arranged along the second direction Y. One second touch electrode of the 6 second touch electrodes 6 includes a plurality of second sub-electrodes 601 arranged along the first direction X.

In some embodiments, as shown in FIGS. 8-11, the plurality of touch conductive layers 201 include a first touch conductive layer 201-1 and a second touch conductive layer 201-1 located at a side of the first touch conductive layer 201-1 away from the display substrate 1.

The touch layer 2 further includes a touch insulating layer 202 located between the first touch conductive layer 201-1 and the second touch conductive layer 201-2.

The first sub-electrode 501 and the second sub-electrode 601 are located in one of the touch conductive layers 201, and the bridging electrode 502 is located in the other one of the touch conductive layers 201. The bridging electrode 502 is electrically connected with the first sub-electrode 501 through a first through hole 3 penetrating through the touch insulating layer 202.

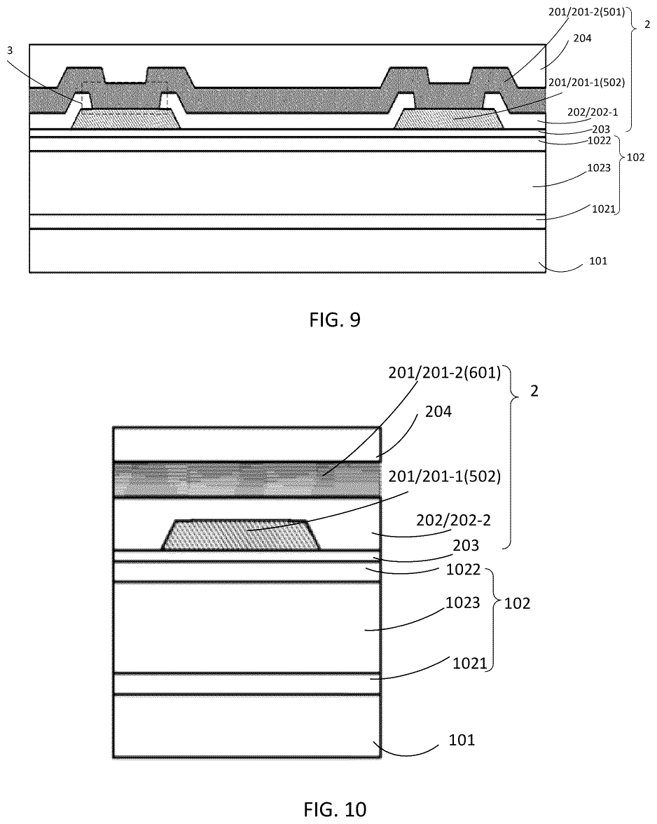

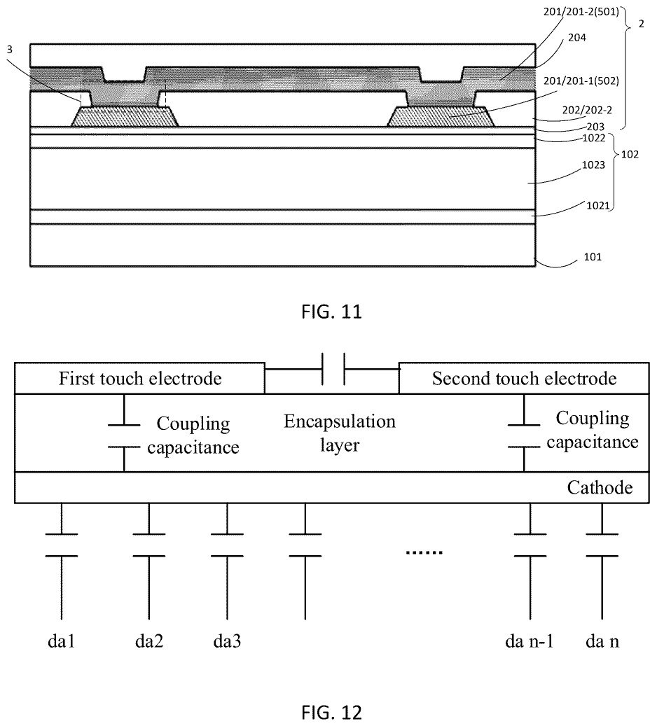

It should be noted that FIG. 8 is a sectional view taken along EE′ in FIG. 2. FIG. 9 is a sectional view taken along FF′ in FIG. 2. FIG. 10 is another sectional view taken along EE′ in FIG. 2. FIG. 11 is another sectional view taken along FF′ in FIG. 2. In FIG. 8 to FIG. 11, the first sub-electrode 501 and the second sub-electrode 601 are located in the second touch conductive layer 201-2, and the bridging electrode 502 is located in the first touch conductive layer 201-1.

In some embodiments, as shown in FIG. 2, the metal grid structure 7 is formed by interweaving a plurality of metal lines 2011, so that the metal grid structure 7 includes a plurality of grids 701. That is, one grid of the grids 701 is a polygon composed of a plurality of metal lines, or, the metal grid structure 7 is formed by repeatedly and continuously arranging and splicing the grids 701. As shown in FIG. 2, a shape of the grid 701 surrounded by the metal lines 2011 is a rectangle. Alternatively, the shape of the grid surrounded by the metal lines may be a rhombus, triangle, hexagon, etc., or, the shape of the grid surrounded by the metal lines may be a combination of various shapes, such as a combination of pentagon and hexagon, or, the shape of the grid surrounded by the metal lines may include any one or more of triangle, square, rectangle, rhombus, trapezoid, pentagon, and hexagon. In a specific implementation, a pattern of the grid surrounded by the metal lines can be a regular shape or an irregular shape. An edge of the grid may be a straight line or may be a curved line, and embodiments of the present disclosure are not limited herein. The edge of the metal grid structure may also include a pattern of incomplete grids.

In a specific implementation, as shown in FIG. 2, a plurality of cutouts 4 can be arranged on the grid 701. For parts of the touch conductive layer 201 in the same layer that need to be insulated from each other, for example, when the grid 701 of the first sub-electrode 501 and the grid 701 of the second sub-electrode 601 are located in the same layer, by providing the cutouts 4 in the pattern of the grid 701 provided on the entire surface, isolation between the grid 701 of the first sub-electrode 501 and the grid 701 of the second sub-electrode 601 can be realized.

The touch electrode according to an embodiment of the present disclosure includes a metal grid structure, the first touch electrode and the second touch electrode in the form of a metal grid structure have advantages of small resistance, small thickness, high response speed and the like. Sensitivity and accuracy of touch recognition can be improved.

In a specific implementation, the grid in the first touch conductive layer and the grid in the second touch conductive layer have the same shape, size and line width of the metal line. An orthographic projection of the grid in the first touch conductive layer on the display substrate and an orthographic projection of the grid in the second touch conductive layer on the display substrate have approximately overlapped regions.

In some embodiments, the display region AA includes a plurality of sub-pixels. As shown in FIG. 3, the display substrate 1 includes a base substrate 101, a pixel defining layer 105 and a plurality of light-emitting devices 104 located at a side of the base substrate 101, a driving circuit layer 103 located between the light-emitting devices 104 and the base substrate 101, and an encapsulation layer 102 located at a side of the pixel defining layer 105 and the light-emitting devices 104 away from the base substrate. The light-emitting devices 104 correspond to the sub-pixels one by one.

In some embodiments, as shown in FIG. 3, one light-emitting device of the light-emitting devices 104 includes an anode 1041, a light-emitting functional layer 1042, and a cathode 1043. The pixel defining layer 105 includes a plurality of opening regions 1051, and the opening regions 1051 are in one-to-one correspondence with the sub-pixels. The pixel defining layer 105 covers an edge of the anode 1041. An orthographic projection of one opening region 1051 of the opening regions 1051 on the base substrate 101 falls within an orthographic projection of the anode 1041 on the base substrate 101. The light-emitting functional layer 1042 is located at a side of the anode 1041 and the pixel defining layer 105 away from the base substrate 101. The cathode 1043 is located at a side of the light-emitting functional layer 1042 away from the base substrate 101.

In a specific implementation, if the light-emitting device is an organic light-emitting diode, the light-emitting functional layer at least includes an organic light-emitting layer, and may further include at least one of: an electron injection layer, a hole blocking layer, an electron transport layer, a hole transport layer, an electron blocking layer, a hole injection layer.

In some embodiments, as shown in FIG. 3, the driving circuit layer 103 includes pixel driving circuits corresponding to the light-emitting devices 104 one by one and driving the light-emitting devices 104 to emit light. One pixel driving circuit of the pixel driving circuits includes, for example, a thin film transistor 1031 and a capacitor 1032. It should be noted that only one thin film transistor 1031 and one capacitor 1032 are shown in FIG. 3. In a specific implementation, the pixel driving circuit may further include a greater number of thin film transistors and capacitors.

It should be noted that in FIG. 3, the transistor 1031 is illustrated as an example of a top gate structure. That is, a gate G is located at a side of an active layer 10311 away from the base substrate 101. A first electrode 10321 of the capacitor 1032 is arranged in the same layer as the gate G. A second electrode 10322 of the capacitor 1032 is located between a film layer where the gate G is located and a film layer where a source S and a drain D are located. The display substrate 1 further includes a first buffer layer 1033 located between the base substrate 101 and the active layer 10311, a first gate insulating layer 1034 located between the gate G and the active layer 10311, a second gate insulating layer 1035 located between the first electrode 10321 and the second electrode 10322, an interlayer insulating layer 1036 located between the second electrode 10322 and the source S and drain D, and a first planarization layer 106 located between the source S and drain D and the anode 1041.

In some embodiments, the anode is connected with the drain through a through hole penetrating the first planarization layer.

Alternatively, in some embodiment, as shown in FIG. 3, the display substrate 1 further includes a transfer electrode 1039 located between the source S and the drain D and the anode electrode 1041, a passivation layer 1037 located between the source S and drain D and the transfer electrode 1039, a second planarization layer 1038 located between the passivation layer 1037 and the transfer electrode 1039. The anode 1041 is connected with the transfer electrode 1039 through a through hole penetrating the first planarization layer 106. The transfer electrode 1039 is connected with the drain D through a through hole penetrating the second planarization layer 1038 and the passivation layer 1037.

In some embodiments, as shown in FIG. 2, an orthographic projection of the opening region 1051 on the base substrate falls within an orthographic projection of the grid 701 on the base substrate 101. That is, an orthographic projection of the metal line 2011 on the base substrate and the orthographic projection of the opening region 1051 on the base substrate do not overlap with each other, to prevent the metal line 2011 from affecting normal display of the display substrate.

In some embodiments, as shown in FIG. 3, the touch layer 2 further includes a second buffer layer 203 located between the first touch conductive layer (not shown) and the encapsulation layer 102, and a protective layer 204 located at a side of the second touch conductive layer 201-2 away from the base substrate 101.

The touch display panel according to an embodiment of the present disclosure adopts an FMLOC process, that is, the touch layer is directly manufactured on stacked light-emitting structure layer and encapsulation layer, so that a thickness of the touch display panel can be reduced, which is beneficial to realizing lightness and thinness of the touch display product.

In some embodiments, as shown in FIG. 6, the touch layer further includes a plurality of touch wires 8. The plurality of touch wires 8 includes a plurality of first touch wires 801 and a plurality of second touch wires 802. The touch display panel further includes a plurality of bonding electrodes 9.

One touch wire 8 of the touch wires 8 extends from one end of the first touch electrode 5 or the second touch electrode 6 through the peripheral region NA and is electrically connected with one bonding electrode 9 of the bonding electrodes 9.

In some embodiments, the touch wire further includes a metal grid structure formed by interweaving metal lines.

In some embodiments, the touch wire is located in at least one touch conductive layer.

In some embodiments, the touch wire is located in the first touch conductive layer or the second touch conductive layer.

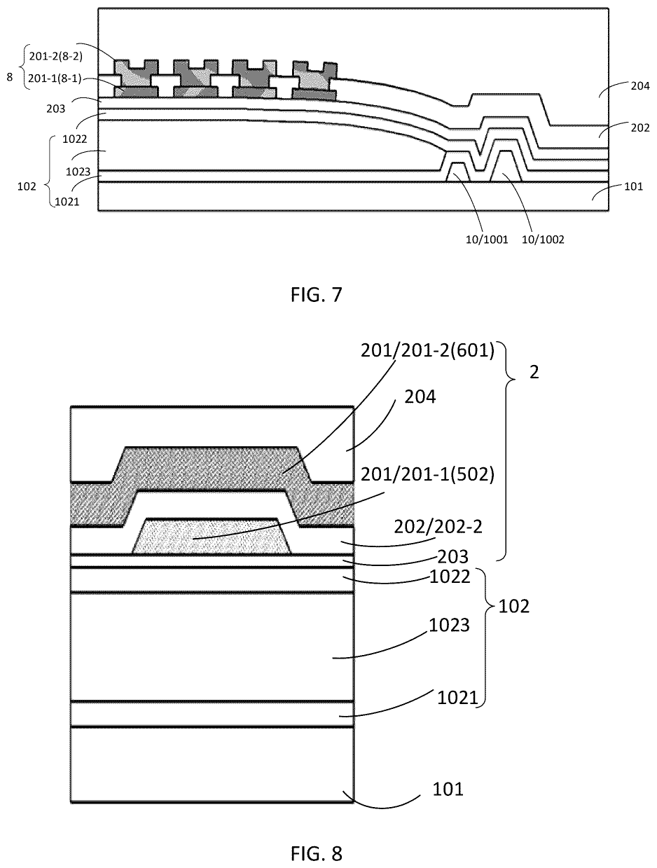

Alternatively, in some embodiments, as shown in FIG. 7, the touch wire 8 includes a first sub-wire 8-1 located in the first touch conductive layer 201-1, and a second sub-wire 8-2 located in the second touch conductive layer 201-2. The second sub-wire 8-2 is electrically connected with the first sub-wire 8-1 through a through hole penetrating the touch insulating layer 202. That is, double-layer wiring of the touch wire can reduce impedance of the touch wire by connecting the first sub-wire and the second sub-wire in parallel.

In some embodiments, a size of the touch display panel is less than 10 inches, and a line width of the metal line is less than or equal to 4 micrometers (μm).

In some embodiments, the size of the touch display panel is greater than or equal to 10 inches, the line width of the metal line is greater than or equal to 5 μm and less than or equal to 6.5 μm.

Next, the RC Loading can be reduced by increasing the line width of the metal line. In the related art, the line width of the metal line in the touch display panel with medium or large size (i.e., the size of the touch display panel is greater than or equal to 10 inches) is generally 2.5 μm to 4.5 μm. As shown in Table 1, when the line width of the metal line increases from 4 μm to 6 μm, it can be seen that the capacitance of the touch electrode only increases by 4.46%, and the resistance of the touch electrode is reduced by 34.61%. For the touch display panel with medium and large size, RC Loading, when the active stylus is used for touch control, the attenuation of the touch control signal can be significantly reduced.

TABLE 1

| Line width of metal line | 4 μm | 6 μm |
|---|---|---|
| Total capacitance (pF) | 471 | 492 |
| Total Resistance (Ohms) | 1040 | 680 |

In some embodiments, a thickness of the first touch conductive layer is greater than or equal to 0.34 μm, and a thickness of the second touch conductive layer is greater than or equal to 0.42 μm.

It should be noted that in the conventional touch display panel with small size, the thickness of the first touch conductive layer is about 0.25 μm, and the thickness of the second touch conductive layer is about 0.41 μm. However, when the size of the touch display panel increases, if the thickness of the touch conductive layer is constant, the RC loading of the touch display panel with increased size is several times of the RC loading of the touch display panel with small size, and signal attenuation of the active stylus is large. According to the touch display panel according to an embodiment of the present disclosure, the thickness of the first touch conductive layer is greater than or equal to 0.34 μm, the thickness of the second touch conductive layer is greater than or equal to 0.42 μm, which is equivalent to increasing the thickness of the touch conductive layer. The capacitance of the touch conductive layer can be reduced, reducing the RC loading and reducing the signal attenuation of the active stylus.

In some embodiments, as shown in FIG. 8 and FIG. 9, the touch insulating layer 202 is an inorganic touch insulating layer 202-2. The thickness of the first touch conductive layer 201-1 is less than or equal to 0.42 μm. The thickness of the inorganic touch insulating layer 202-2 is greater than or equal to 0.35 μm and less than or equal to 0.43 μm. The thickness of the second touch conductive layer 201-2 is less than or equal to 0.5 μm.

When the touch insulating layer 202 is an inorganic touch insulating layer 202-2, the thickness of the first touch conductive layer 201-1 is greater than or equal to 0.34 μm and less than or equal to 0.42 μm. The thickness of the second touch conductive layer 201-2 is greater than or equal to 0.42 μm and less than or equal to 0.72 μm.

It should be noted that, as shown in FIG. 8 and FIG. 9, a side surface of a pattern of the first touch conductive layer 201-1 is an inclined surface. That is, the pattern of the first touch conductive layer 201-1 has a slope angle. In the related art, the thickness of the touch insulating layer is about 0.33 μm. However, since the thickness of the first touch conductive layer is increased, if the touch insulation layer is too thin, the two touch conductive layers may be short-circuited at the slope angle.

According to the touch display panel according to an embodiment of the present disclosure, the thickness of the inorganic touch insulating layer is greater than or equal to 0.35 μm. That is, the thickness of the touch insulating layer is correspondingly increased while the thickness of the touch conductive layer is increased, and the touch insulating layer is prevented from being unable to cover the slope angle of the touch conductive layer. Moreover, after an inorganic material is deposited on a metal pattern, a surface of the inorganic material away from the base substrate is not a planarized surface, and the inorganic insulating layer formed also has a slope angle at the slope angle of the metal line. If the thickness of the first touch conductive layer is too thick, the slope angle is too large to cause climbing difficulty of the inorganic material, and the two touch conductive layers are still short-circuited. In an embodiment of the present disclosure, the thickness of the first touch conductive layer is less than or equal to 0.42 μm, the short circuit caused by the climbing difficulty of the inorganic insulating layer due to the fact that the thickness of the first touch conductive layer is too thick can be avoided, and a yield of the touch display panel can be improved.

Alternatively, in some embodiments, as shown in FIG. 10 and FIG. 11, the touch insulating layer 202 is an organic touch insulating layer 202-2. The thickness of the first touch conductive layer 201-1 is less than or equal to 0.72 μm. A thickness of the organic touch insulating layer 202-2 is greater than or equal to 1.4 micrometers and less than or equal to 1.8 micrometers. The thickness of the second touch conductive layer 201-2 is less than or equal to 0.72 μm.

When the touch insulating layer 202 is the organic touch insulating layer 202-2, the thickness of the first touch conductive layer 201-1 is greater than or equal to 0.34 μm and less than or equal to 0.72 μm. The thickness of the second touch conductive layer 201-2 is greater than or equal to 0.42 μm and less than or equal to 0.72 μm.

According to the touch display panel according to an embodiment of the present disclosure, the thickness of the organic touch insulating layer is greater than or equal to 1.4 μm. That is, the thickness of the touch insulating layer is correspondingly increased while the thickness of the touch conductive layer is increased, avoiding that the touch insulating layer cannot cover the slope angle of the touch conductive layer, and avoiding the short circuit of the first touch conductive layer and the second touch conductive layer at the slope angle. The thickness of the organic touch insulating layer is less than or equal to 1.8 μm, so that the film layer is prevented from being too thick to influence coupling between touch electrodes. In addition, after the organic material is coated on the metal pattern, the surface of the organic material far away from the base substrate is a planarized surface, the organic insulating layer formed is a film layer with a planarized surface above the slope angle of the metal line. Therefore, the first touch conductive layer with larger thickness cannot be broken at the slope angle, compared with a condition that the inorganic touch insulating layer covers the first touch conductive layer, the thickness of the first touch conductive layer can be further increased, decreasing RC loading and reducing signal attenuation of the active stylus.

In some embodiments, the thickness of the first touch conductive layer is equal to the thickness of the second touch conductive layer.

In a specific implementation, the inorganic touch insulating layer may be selected when the size of the touch display panel is larger than 10 inches and smaller than 15 inches. The organic insulating layer may be selected when the size of the touch display panel is greater than or equal to 15 inches.

In some embodiments, the touch conductive layer is a stack layer of titanium/aluminum/titanium. A thickness of the titanium layer is greater than or equal to 0.02 μm and less than or equal to 0.05 μm. When the touch insulating layer is an inorganic touch insulating layer, in the first touch conductive layer, a thickness of the aluminum layer is more than or equal to 0.29 μm and less than or equal to 0.4 μm. In the second touch conductive layer, a thickness of the aluminum layer is greater than or equal to 0.37 μm and less than or equal to 0.48 μm. When the touch insulating layer is an organic touch insulating layer, in the touch conductive layer, a thickness of the aluminum layer is more than or equal to 0.29 μm and less than or equal to 0.7 μm. In the second touch conductive layer, a thickness of the aluminum layer is greater than or equal to 0.37 μm and less than or equal to 0.7 μm.

Next, it is illustrated that the signal attenuation of the active stylus can be reduced by increasing the thickness of the touch conductive layer. In the related art, when the thickness of the first touch conductive layer is 0.25 μm and the thickness of the second touch conductive layer is 0.41 μm, the active stylus has a signal attenuation of 30.3% at 1.8 MHz. Touch performance of the stylus cannot be guaranteed when the display size is large. As shown in Table 2, when the thickness of the first touch conductive layer is increased to 0.38 μm and the thickness of the second touch conductive layer is increased to 0.46 μm, the signal attenuation of the active stylus is reduced to 12.73% at 1.8 MHz. When the thickness of the first touch conductive layer and the thickness of the second touch conductive layer are increased to 0.68 μm, the signal attenuation of the active stylus is reduced to 4.8% at 1.8 MHz, which can significantly reduce the touch signal attenuation.

TABLE 2

| | | | |
|---|---|---|---|
| Thickness of the first touch conductive layer | 0.25 | 0.38 | 0.68 |
| (μm) | | | |
| Thickness of the second touch conductive layer | 0.41 | 0.46 | 0.68 |
| (μm) | | | |
| Active stylus signal attenuation @1.8 MHz | 30.3% | 12.7% | 4.8% |

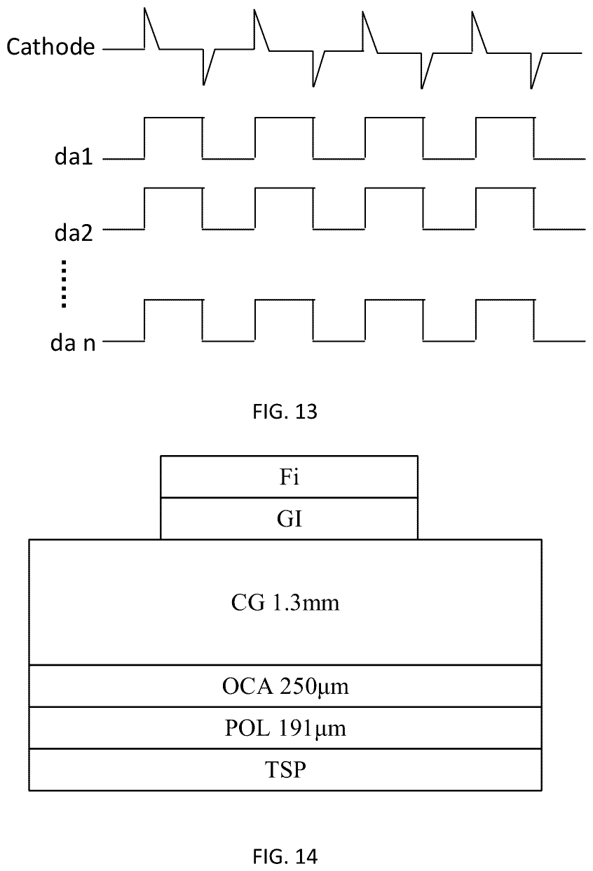

It should be noted that, as a size of a product increases, RC loading may increase and signal attenuation may increase. As shown in FIG. 12 and FIG. 13, a display signal da is coupled to a cathode to generate display noise. As the size of the product increases, a noise intensity of the display signal da coupled to the cathode increases, and coupling capacitance between the touch electrode and the cathode also increases. As a result, the noise of touch display product with medium and large size is large. In addition, the touch display panel according to an embodiment of the present disclosure can also be touched by using a touch glove.

In some embodiments, for a vehicle-mounted touch display product, as shown in FIG. 14, a Polarizer (POL), an Optically Clear Adhesive (OCA), and a Cover Glass (CG) need to be stacked on a touch screen panel (TSP). A thickness of POL 191 is μm, a thickness of OCA 250 is μm, a thickness of CG 1.3 is mm. That is, a thickness of light transmission film layers stacked on the TSP is thicker. When the touch glove G1 is used for touch control, a distance between a finger Fi and the TSP and a distance between the touch glove G1 and the TSP are large, and problems such as ghost points and unreported points caused by substandard of a signal-to-noise ratio (SNR) may occur.

In some embodiments, as shown in FIG. 3, the encapsulation layer 102 includes at least one organic encapsulation layer 1023 at a side of the pixel defining layer 105 away from the base substrate 101.

In the display region, a difference between a minimum thickness of the organic encapsulation layer 1023 included in the encapsulation layer 102 in a direction perpendicular to the base substrate 101 and the size h2 of the touch display panel is great than or equal to 1 micrometer. In the display region, the minimum thickness of the organic encapsulating layer 1023 included in the encapsulation layer 102 in the direction perpendicular to the base substrate 101 is t a thickness of the organic encapsulation layer 1023 corresponding to a position where the pixel defining layer 105 is located in the direction perpendicular to the base substrate 101.

According to the touch display panel according to an embodiment of the present disclosure, in the display region, the difference between the minimum thickness of the organic encapsulation layer in the direction perpendicular to the base substrate and the size h2 of the touch display panel is greater than or equal to 1, the thickness of the organic encapsulation layer can be adjusted according to the size of the touch display panel. When the size of the touch display panel is increased, the thickness of the organic encapsulation layer is also increased. Therefore, the distance between the touch conductive layer and the cathode can be increased, the coupling capacitance between the touch electrode and the cathode can be reduced, and the noise can be reduced. The signal-to-noise ratio and the touch accuracy are improved, avoiding problems of ghost points, unreported points and the like caused by using the active stylus or touch glove for touch control.

In some embodiments, as shown in FIG. 3, the encapsulation layer 102 includes an organic encapsulation layer 1023.

In some embodiments, as shown in FIG. 3, the encapsulation layer 102 further includes a first inorganic encapsulation layer 1021, and a second inorganic encapsulation layer 1022 located at a side of the first inorganic encapsulation layer 1021 away from the base substrate 101. The at least one organic encapsulation layer 1023 includes a first organic encapsulation layer 1023-1 located between the first inorganic encapsulation layer 1021 and the second inorganic encapsulation layer 1022.

In some embodiments, in the display region, a difference between a minimum thickness h3 of the first organic encapsulation layer 1023-1 in the direction perpendicular to the base substrate 101 and the size h2 of the touch display panel is equal to 1 micrometer.

According to the touch display panel according to an embodiment of the present disclosure, the difference between the minimum thickness of the single layer of the first organic encapsulation layer in the direction perpendicular to the base substrate and the size h2 of the touch display panel is equal to 1 micrometer, the thickness of the first organic encapsulation layer can be adjusted according to the size of the touch display panel. When the size of the touch display panel is increased, the thickness of the organic encapsulation layer is also increased. Therefore, the distance between the touch conductive layer and the cathode can be increased, the coupling capacitance between the touch electrode and the cathode can be reduced, and the noise can be reduced. The signal-to-noise ratio and the touch accuracy are improved, avoiding problems of ghost points, unreported points and the like caused by using the active stylus or touch glove for touch control.

In some embodiments, the size of the touch display panel is larger than 10 inches. In the display region AA, a minimum thickness h3 of the first organic encapsulating layer 1023-1 in a direction perpendicular to the base substrate 101 is greater than or equal to 14 micrometers and less than or equal to 18 micrometers.

In some embodiments, in the peripheral region, as shown in FIG. 7, the touch display panel further includes a plurality of retaining walls 10. An orthographic projection of the retaining walls 10 on the base substrate 101 surrounds the display region (not shown). The plurality of retaining walls 10 include a first retaining wall 1001 and a second retaining wall 1002 located at a side of the first retaining wall 1001 away from the display region (not shown).

In some embodiments, the first organic encapsulating layer does not exceed the first retaining wall 1001.

According to the touch display panel according to an embodiment of the present disclosure, when the size of the touch display panel is larger than 10 inches, the minimum thickness of the single layer of the first organic encapsulation layer in the direction perpendicular to the base substrate is greater than or equal to 14 micrometers, which is beneficial to increasing the distance between the touch conductive layer and the cathode. The minimum thickness of the single layer of the first organic encapsulating layer in the direction perpendicular to the base substrate is less than or equal to 18 micrometers, which can prevent the organic encapsulation layer from exceeding the first retaining wall, and the process difficulty can be reduced.

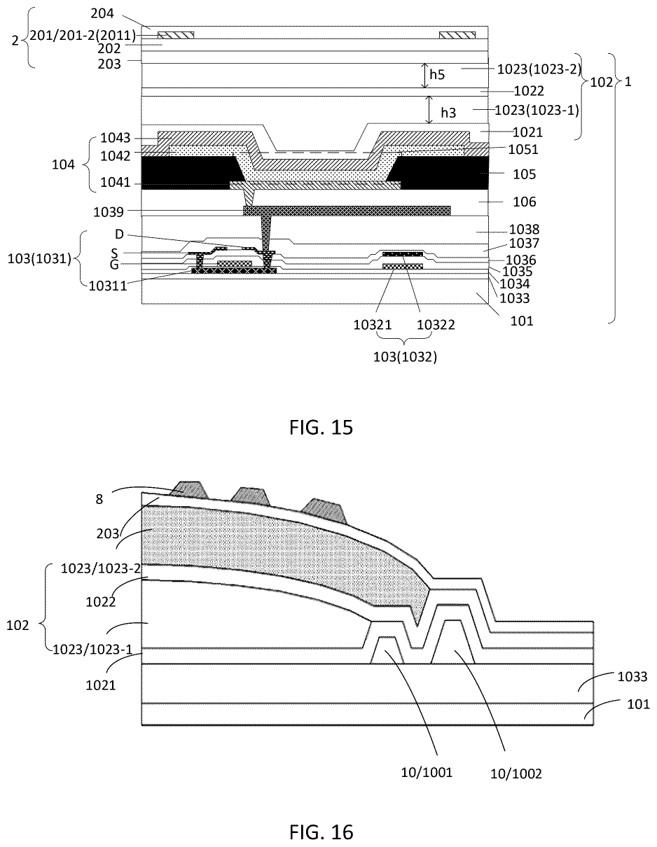

Alternatively, in some embodiments, as shown in FIG. 15 and FIG. 16, the encapsulation layer 102 further includes a first inorganic encapsulation layer 1021, and a second inorganic encapsulation layer 1022 located at a side of the first inorganic encapsulation layer 1021 away from the base substrate 101. The at least one organic encapsulation layer 1023 includes a first organic encapsulation layer 1023-1 located between the first inorganic encapsulation layer 1021 and the second inorganic encapsulation layer 1022, and a second organic encapsulation layer 1023-2 located at a side of the second inorganic encapsulation layer 1022 away from the first organic encapsulation layer 1023-1.

The touch display panel according to an embodiment of the present disclosure includes two organic encapsulation layers, which can increase the overall thickness of the encapsulation layers. Therefore, the distance between the touch conductive layer and the cathode can be increased, the coupling capacitance between the touch electrode and the cathode can be reduced, the noise can be reduced, and the signal-to-noise ratio and the touch accuracy are improved.

In some embodiments, as shown in FIG. 15, a minimum thickness h5 of the second organic encapsulating layer 1023-2 in the display region is less than a minimum thickness h3 of the first organic encapsulating layer 1023-1 in the display region.

In some embodiments, as shown in FIG. 16, an orthographic projection of the second organic encapsulation layer 1023-2 on the base substrate 101 covers an orthographic projection of the first retaining wall 1001 on the base substrate 101. The orthographic projection of the second organic encapsulation layer 1023-2 on the base substrate 101 does not exceed an orthographic projection of the second retaining wall 1002 on the base substrate 101.

According to the touch display panel according to an embodiment of the present disclosure, the minimum thickness of the second organic encapsulation layer in the display region is less than the minimum thickness of the first organic encapsulation layer in the display region, the second organic encapsulation layer can be prevented from exceeding the second retaining wall, and the process difficulty can be reduced.

In some embodiments, the size of the touch display panel is greater than 10 inches. The minimum thickness of the first organic encapsulating layer 1023-1 in the display region AA is greater than or equal to 12 micrometers and less than or equal to 18 micrometers. The minimum thickness of the second organic encapsulating layer 1023-2 in the display region AA is greater than or equal to 8 micrometers and less than or equal to 14 micrometers.

Next, the touch display panel according to an embodiment of the present disclosure which can improve a touch signal amount for touch control by using the active stylus and the touch glove is taken as an example. A1 represents that the encapsulating layer includes a single layer of the organic encapsulating layer, and the minimum thickness of the organic encapsulating layer in a direction perpendicular to the base substrate is 12 μm. A2 represents that the encapsulation layer includes a single layer of the organic encapsulation layer, and the minimum thickness of the organic encapsulation layer in a direction perpendicular to the base substrate is 17 μm. A3 represents that the encapsulating layer includes a first organic encapsulating layer and a second organic encapsulation layer. The minimum thickness of the second organic encapsulation layer in the direction perpendicular to the base substrate is 17 μm. The minimum thickness of the first the organic encapsulation layer in the direction perpendicular to the base substrate is 12 μm.

In the related art, the minimum thickness of an organic encapsulation layer of a mobile phone product in a direction perpendicular to a base substrate is about 8 μm to 12 μm. As shown in Table 3, when the encapsulation layer includes a single layer of the organic encapsulation layer, and the minimum thickness of the organic encapsulation layer in the direction perpendicular to the base substrate is 12 μm, the coupling capacitance of the product with large size of 13 inches and above exceeds the specification limit (600 pF). When the minimum thickness of the organic encapsulation layer in the direction perpendicular to the base substrate is increased to 17 μm, the coupling capacitance of the product with large size of 13 inches to 15 inches is less than 600 pF, which meets the specification limit. However, the coupling capacitance of the product with large size of 16 inches and above is greater than 600 pF, which exceeds the specification limit. When the encapsulation layer includes a first organic encapsulation layer and a second organic encapsulation layer, the minimum thickness of the second organic encapsulation layer in the direction perpendicular to the base substrate is 17 μm, the minimum thickness in the direction is 12 μm, and the coupling capacitance of the product with large size of 13 inches to 18 inches is less than 600 pF, which meets the specifications. The coupling capacitance for the two layers of organic encapsulation layers is 30% lower than the coupling capacitance for the single layer of the organic encapsulation layer with the thickness of 17 μm.

TABLE 3

| | 13 | 14 | 15 | 16 | 17 | 18 |
|---|---|---|---|---|---|---|
| | inches | inches | inches | inches | inches | inches |
| A1 | 620 pF | 666 pF | 720 pF | 764 pF | 820 pF | 860 pF |
| A2 | 497 pF | 533 pF | 576 pF | 611 pF | 654 pF | 690 pF |
| A3 | 340 pF | 364 pF | 394 pF | 418 pF | 447 pF | 472 pF |

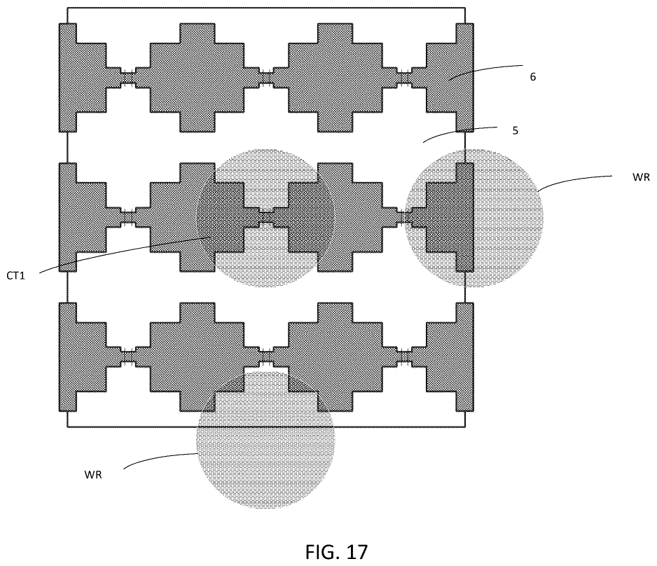

FIG. 17 is a schematic diagram of the active stylus P1 touching the first touch electrode 5 and the second touch electrode 6. At different positions (including a center region CT and edge regions Wr), the coupling capacitance between the active stylus P1 and the first touch electrode 5 and the coupling capacitance between the active stylus P1 and the second touch electrode 6 is shown in Table 4. Cp_t represents the coupling capacitance between the active stylus P1 and the second touch electrode 6, Cp_r represents the coupling capacitance between the active stylus P1 and the first touch electrode 5, and the unit of the capacitance is farad (fF). According to Table 4, when the thickness and the number of layers of the organic encapsulation layer are increased, the coupling capacitance between the active stylus and the touch electrode increases, that is, the signal amount of the active stylus increases.

TABLE 4

| | | A1 | A2 | A3 |
|---|---|---|---|---|
| CT | Cp_t (fF) | 28.2 | 30.6 | 34.5 |
| | Cp_r(fF) | 32.8 | 35.6 | 40.1 |
| Wr | Cp_t(fF) | 17.3 | 18.8 | 21.2 |
| | Cp_r(fF) | 20.2 | 21.9 | 24.9 |

Table 5 shows the signal attenuation of the active stylus of touch display panels of different sizes. According to Table 5, in the related art, when the encapsulation layer includes a single layer of organic encapsulation layer and the minimum thickness of the organic encapsulation layer in the direction perpendicular to the base substrate is 12 μm, for the touch display panel with large size, the signal attenuation of the active stylus is more than 30%, and the signal attenuation is large. The touch effect of the active stylus cannot be guaranteed. As the thickness of the organic encapsulation layer increases to 17 μm, the signal attenuation of the active stylus decreases significantly. When the encapsulation layer includes two layers of organic encapsulation layers, the signal attenuation of the active stylus is further reduced.

TABLE 5

| | Size | | | | | |
|---|---|---|---|---|---|---|
| | 13 | 14 | 15 | 16 | 17 | 18 |
| | inches | inches | inches | inches | inches | inches |
| A1 Active | 36% | 38% | 40% | 42% | 44% | 46% |
| stylus signal | | | | | | |
| attenuation | | | | | | |
| A2 Active | 19% | 21% | 22% | 24% | 25% | 27% |
| Stylus Signal | | | | | | |
| Attenuation | | | | | | |
| A3 Active | 12% | 13% | 14% | 16% | 17% | 18% |
| Stylus Signal | | | | | | |
| Attenuation | | | | | | |

When the touch signal amount for touch control by using the touch gloves is shown in Table 6, as the thickness and the number of layers of the organic encapsulation layer increase, the touch signal amount of the glove is improved by about 30%, and the coupling capacitance is reduced. The increase of the thickness and the number of layers of the organic encapsulation layer can improve the SNR of the glove touch control and realize the application effect of the vehicle-mounted glove touch control product.

TABLE 6

| Glove thickness | 2 mm | 4 mm |
|---|---|---|
| A2 signal amount | 0.036 pF | 0.023 pF |
| A3 signal amount | 0.046 pF | 0.029 pF |

In the related art, as shown in FIGS. 12 and 13, the display signal da is coupled to the cathode to generate display noise. As the size of the product increases, the noise intensity of the display signal da coupled to the cathode increases, and the coupling capacitance between the touch electrode and the cathode also increases. As a result, the noise of the touch display product with medium and large size is large. For a vehicle-mounted touch display product, as shown in FIG. 14, a Polarizer (POL), an Optically Clear Adhesive (OCA), and a Cover Glass (CG) need to be stacked on a touch screen panel (TSP). A thickness of POL 191 is μm, a thickness of OCA 250 is μm, a thickness of CG 1.3 is mm. That is, a thickness of light transmission film layers stacked on the TSP is thicker. When the touch glove G1 is used for touch control, a distance between a finger Fi and the TSP and a distance between the touch glove Gl and the TSP are large, and problems such as ghost points and unreported points caused by substandard of a signal-to-noise ratio (SNR) may occur.

In view of this, embodiments of the present disclosure provide a touch display panel, as shown in FIG. 3 and FIG. 15, the touch display panel includes a display region AA and a peripheral region NA surrounding the display region AA. The touch display panel includes:
a display substrate 1; the display substrate 1 includes a base substrate 101, a pixel defining layer 105 and an encapsulation layer 102 at a side of the base substrate 101. The pixel defining layer 105 includes a plurality of opening regions 1051, and the encapsulation layer 102 includes at least one organic encapsulation layer 1023 at a side of the base substrate 101. A difference between a minimum thickness of the organic encapsulation layer 1023 included in the encapsulation layer 102 in the display region in a direction perpendicular to the base substrate 101 and a size h2 of the touch display panel is greater than or equal to 1 micrometer. The minimum thickness of the organic encapsulation layer 1023 included in the encapsulation layer 102 in the display region in the direction perpendicular to the base substrate 101 is a thickness of the organic encapsulation layer 1023 corresponding to a position where the pixel defining layer 105 is located in the direction perpendicular to the base substrate 101; and
a touch layer 2, located at a display side of the display substrate 1.

According to the touch display panel according to an embodiment of the present disclosure, in the display region, the difference between the minimum thickness of the organic encapsulation layer in the direction perpendicular to the base substrate and the size h2 of the touch display panel is greater than or equal to 1, the thickness of the organic encapsulation layer can be adjusted according to the size of the touch display panel. When the size of the touch display panel is increased, the thickness of the organic encapsulation layer is also increased. Therefore, the distance between the touch conductive layer and the cathode can be increased, the coupling capacitance between the touch electrode and the cathode can be reduced, and the noise can be reduced. The signal-to-noise ratio and the touch accuracy are improved, avoiding problems of ghost points, unreported points and the like caused by using the active stylus or touch glove for touch control.

In some embodiments, as shown in FIG. 3, the encapsulation layer 102 includes an organic encapsulation layer 1023.

In some embodiments, as shown in FIG. 3, the encapsulation layer 102 further includes a first inorganic encapsulation layer 1021, and a second inorganic encapsulation layer 1022 located at a side of the first inorganic encapsulation layer 1021 away from the base substrate 101. The at least one organic encapsulation layer 1023 includes a first organic encapsulation layer 1023-1 located between the first inorganic encapsulation layer 1021 and the second inorganic encapsulation layer 1022.

In some embodiments, in the display region AA, a difference between a minimum thickness h3 of the first organic encapsulation layer 1023-1 in the direction perpendicular to the base substrate 101 and the size h2 of the touch display panel is equal to 1 micrometer.

According to the touch display panel according to an embodiment of the present disclosure, the difference between the minimum thickness of the single layer of the first organic encapsulation layer in the direction perpendicular to the base substrate and the size h2 of the touch display panel is equal to 1 micrometer, the thickness of the first organic encapsulation layer can be adjusted according to the size of the touch display panel. When the size of the touch display panel is increased, the thickness of the organic encapsulation layer is also increased. Therefore, the distance between the touch conductive layer and the cathode can be increased, the coupling capacitance between the touch electrode and the cathode can be reduced, and the noise can be reduced. The signal-to-noise ratio and the touch accuracy are improved, avoiding problems of ghost points, unreported points and the like caused by using the active stylus or touch glove for touch control.

In some embodiments, the size of the touch display panel is larger than 10 inches. In the display region AA, a minimum thickness h3 of the first organic encapsulating layer 1023-1 in a direction perpendicular to the base substrate 101 is greater than or equal to 14 micrometers and less than or equal to 18 micrometers.

In some embodiments, in the peripheral region, as shown in FIG. 7, the touch display panel further includes a plurality of retaining walls 10. An orthographic projection of the retaining walls 10 on the base substrate 101 surrounds the display region (not shown). The plurality of retaining walls 10 include a first retaining wall 1001 and a second retaining wall 1002 located at a side of the first retaining wall 1001 away from the display region (not shown).

In some embodiments, the first organic encapsulating layer does not exceed the first retaining wall 1001.

According to the touch display panel according to an embodiment of the present disclosure, when the size of the touch display panel is larger than 10 inches, the minimum thickness of the single layer of the first organic encapsulation layer in the direction perpendicular to the base substrate is greater than or equal to 14 micrometers, which is beneficial to increasing the distance between the touch conductive layer and the cathode. The minimum thickness of the single layer of the first organic encapsulating layer in the direction perpendicular to the base substrate is less than or equal to 18 micrometers, which can prevent the organic encapsulation layer from exceeding the first retaining wall, and the process difficulty can be reduced.

Alternatively, in some embodiments, as shown in FIG. 15 and FIG. 16, the encapsulation layer 102 further includes a first inorganic encapsulation layer 1021, and a second inorganic encapsulation layer 1022 located at a side of the first inorganic encapsulation layer 1021 away from the base substrate 101. The at least one organic encapsulation layer 1023 includes a first organic encapsulation layer 1023-1 located between the first inorganic encapsulation layer 1021 and the second inorganic encapsulation layer 1022, and a second organic encapsulation layer 1023-2 located at a side of the second inorganic encapsulation layer 1022 away from the first organic encapsulation layer 1023-1.

The touch display panel according to an embodiment of the present disclosure includes two organic encapsulation layers, which can increase the overall thickness of the encapsulation layers. Therefore, the distance between the touch conductive layer and the cathode can be increased, the coupling capacitance between the touch electrode and the cathode can be reduced, the noise can be reduced, and the signal-to-noise ratio and the touch accuracy are improved.

In some embodiments, as shown in FIG. 15, a minimum thickness h5 of the second organic encapsulating layer 1023-2 in the display region is less than a minimum thickness h3 of the first organic encapsulating layer 1023-1 in the display region.

In some embodiments, as shown in FIG. 16, an orthographic projection of the second organic encapsulation layer 1023-2 on the base substrate 101 covers an orthographic projection of the first retaining wall 1001 on the base substrate 101. The orthographic projection of the second organic encapsulation layer 1023-2 on the base substrate 101 does not exceed an orthographic projection of the second retaining wall 1002 on the base substrate 101.

According to the touch display panel according to an embodiment of the present disclosure, the minimum thickness of the second organic encapsulation layer in the display region is less than the minimum thickness of the first organic encapsulation layer in the display region, the second organic encapsulation layer can be prevented from exceeding the second retaining wall, and the process difficulty can be reduced.

In some embodiments, the size of the touch display panel is greater than 10 inches. The minimum thickness of the first organic encapsulating layer 1023-1 in the display region AA is greater than or equal to 12 micrometers and less than or equal to 18 micrometers. The minimum thickness of the second organic encapsulating layer 1023-2 in the display region AA is greater than or equal to 8 micrometers and less than or equal to 14 micrometers.

The touch display panel according to embodiments of the present disclosure can increase the touch signal amount by increasing the thickness of the organic encapsulation layer. See the Table 3 to Table 6 and related descriptions are not repeated here.

In some embodiments, a plurality of touch conductive layers include a plurality of touch electrodes. As shown in FIG. 4, the plurality of touch electrodes include a plurality of first touch electrodes 5 and a plurality of second touch electrodes 6.

The plurality of first touch electrodes 5 are arranged along a first direction X and extend along a second direction Y. One first touch electrode of the first touch electrodes 5 includes a plurality of first sub-electrodes 501 arranged along the second direction Y, and a bridging electrode 502 electrically connecting two adjacent first sub-electrodes 501.

The plurality of second touch electrodes 6 extend along the first direction X and are arranged along the second direction Y. One second touch electrode of the 6 second touch electrodes 6 includes a plurality of second sub-electrodes 601 arranged along the first direction X.

In some embodiments, as shown in FIGS. 8-11, the plurality of touch conductive layers 201 include a first touch conductive layer 201-1 and a second touch conductive layer 201-1 located at a side of the first touch conductive layer 201-1 away from the display substrate 1.

The touch layer 2 further includes a touch insulating layer 202 located between the first touch conductive layer 201-1 and the second touch conductive layer 201-2.

The first sub-electrode 501 and the second sub-electrode 601 are located in one of the touch conductive layers 201, and the bridging electrode 502 is located in the other one of the touch conductive layers 201. The bridging electrode 502 is electrically connected with the first sub-electrode 501 through a first through hole 3 penetrating through the touch insulating layer 202.

It should be noted that FIG. 8 is a sectional view taken along EE′ in FIG. 2. FIG. 9 is a sectional view taken along FF′ in FIG. 2. FIG. 10 is another sectional view taken along EE′ in FIG. 2. FIG. 11 is another sectional view taken along FF′ in FIG. 2. In FIG. 8 to FIG. 11, the first sub-electrode 501 and the second sub-electrode 601 are located in the second touch conductive layer 201-2, and the bridging electrode 502 is located in the first touch conductive layer 201-1.

In some embodiments, as shown in FIG. 2, the metal grid structure 7 is formed by interweaving a plurality of metal lines 2011, so that the metal grid structure 7 includes a plurality of grids 701. That is, one grid of the grids 701 is a polygon composed of a plurality of metal lines, or, the metal grid structure 7 is formed by repeatedly and continuously arranging and splicing the grids 701. As shown in FIG. 2, a shape of the grid 701 surrounded by the metal lines 2011 is a rectangle. Alternatively, the shape of the grid surrounded by the metal lines may be a rhombus, triangle, hexagon, etc., or, the shape of the grid surrounded by the metal lines may be a combination of various shapes, such as a combination of pentagon and hexagon, or, the shape of the grid surrounded by the metal lines may include any one or more of triangle, square, rectangle, rhombus, trapezoid, pentagon, and hexagon. In a specific implementation, a pattern of the grid surrounded by the metal lines can be a regular shape or an irregular shape. An edge of the grid may be a straight line or may be a curved line, and embodiments of the present disclosure are not limited herein. The edge of the metal grid structure may also include a pattern of incomplete grids.

In a specific implementation, as shown in FIG. 2, a plurality of cutouts 4 can be arranged on the grid 701. For parts of the touch conductive layer 201 in the same layer that need to be insulated from each other, for example, when the grid 701 of the first sub-electrode 501 and the grid 701 of the second sub-electrode 601 are located in the same layer, by providing the cutouts 4 in the pattern of the grid 701 provided on the entire surface, isolation between the grid 701 of the first sub-electrode 501 and the grid 701 of the second sub-electrode 601 can be realized.

The touch electrode according to an embodiment of the present disclosure includes a metal grid structure, the first touch electrode and the second touch electrode in the form of a metal grid structure have advantages of small resistance, small thickness, high response speed and the like. Sensitivity and accuracy of touch recognition can be improved.

In a specific implementation, the grid in the first touch conductive layer and the grid in the second touch conductive layer have the same shape, size and line width of the metal line. An orthographic projection of the grid in the first touch conductive layer on the display substrate and an orthographic projection of the grid in the second touch conductive layer on the display substrate have approximately overlapped regions.

In some embodiments, the display region AA includes a plurality of sub-pixels. As shown in FIG. 3, the display substrate 1 includes a base substrate 101, a pixel defining layer 105 and a plurality of light-emitting devices 104 located at a side of the base substrate 101, a driving circuit layer 103 located between the light-emitting devices 104 and the base substrate 101, and an encapsulation layer 102 located at a side of the pixel defining layer 105 and the light-emitting devices 104 away from the base substrate. The light-emitting devices 104 correspond to the sub-pixels one by one.

In some embodiments, as shown in FIG. 3, one light-emitting device of the light-emitting devices 104 includes an anode 1041, a light-emitting functional layer 1042, and a cathode 1043. The pixel defining layer 105 includes a plurality of opening regions 1051, and the opening regions 1051 are in one-to-one correspondence with the sub-pixels. The pixel defining layer 105 covers an edge of the anode 1041. An orthographic projection of one opening region 1051 of the opening regions 1051 on the base substrate 101 falls within an orthographic projection of the anode 1041 on the base substrate 101. The light-emitting functional layer 1042 is located at a side of the anode 1041 and the pixel defining layer 105 away from the base substrate 101. The cathode 1043 is located at a side of the light-emitting functional layer 1042 away from the base substrate 101.

In a specific implementation, if the light-emitting device is an organic light-emitting diode, the light-emitting functional layer at least includes an organic light-emitting layer, and may further include at least one of: an electron injection layer, a hole blocking layer, an electron transport layer, a hole transport layer, an electron blocking layer, a hole injection layer.

In some embodiments, as shown in FIG. 3, the driving circuit layer 103 includes pixel driving circuits corresponding to the light-emitting devices 104 one by one and driving the light-emitting devices 104 to emit light. One pixel driving circuit of the pixel driving circuits includes, for example, a thin film transistor 1031 and a capacitor 1032. It should be noted that only one thin film transistor 1031 and one capacitor 1032 are shown in FIG. 3. In a specific implementation, the pixel driving circuit may further include a greater number of thin film transistors and capacitors.

It should be noted that in FIG. 3, the transistor 1031 is illustrated as an example of a top gate structure. That is, a gate G is located at a side of an active layer 10311 away from the base substrate 101. A first electrode 10321 of the capacitor 1032 is arranged in the same layer as the gate G. A second electrode 10322 of the capacitor 1032 is located between a film layer where the gate G is located and a film layer where a source S and a drain D are located. The display substrate 1 further includes a first buffer layer 1033 located between the base substrate 101 and the active layer 10311, a first gate insulating layer 1034 located between the gate G and the active layer 10311, a second gate insulating layer 1035 located between the first electrode 10321 and the second electrode 10322, an interlayer insulating layer 1036 located between the second electrode 10322 and the source S and drain D, and a first planarization layer 106 located between the source S and drain D and the anode 1041.

In some embodiments, the anode is connected with the drain through a through hole penetrating the first planarization layer.

Alternatively, in some embodiment, as shown in FIG. 3, the display substrate 1 further includes a transfer electrode 1039 located between the source S and the drain D and the anode electrode 1041, a passivation layer 1037 located between the source S and drain D and the transfer electrode 1039, a second planarization layer 1038 located between the passivation layer 1037 and the transfer electrode 1039. The anode 1041 is connected with the transfer electrode 1039 through a through hole penetrating the first planarization layer 106. The transfer electrode 1039 is connected with the drain D through a through hole penetrating the second planarization layer 1038 and the passivation layer 1037.

In some embodiments, as shown in FIG. 2, an orthographic projection of the opening region 1051 on the base substrate falls within an orthographic projection of the grid 701 on the base substrate 101. That is, an orthographic projection of the metal line 2011 on the base substrate and the orthographic projection of the opening region 1051 on the base substrate do not overlap with each other, to prevent the metal line 2011 from affecting normal display of the display substrate.

In some embodiments, as shown in FIG. 3, the touch layer 2 further includes a second buffer layer 203 located between the first touch conductive layer (not shown) and the encapsulation layer 102, and a protective layer 204 located at a side of the second touch conductive layer 201-2 away from the base substrate 101.

The touch display panel according to an embodiment of the present disclosure adopts an FMLOC process, that is, the touch layer is directly manufactured on stacked light-emitting structure layer and encapsulation layer, so that a thickness of the touch display panel can be reduced, which is beneficial to realizing lightness and thinness of the touch display product.

In some embodiments, as shown in FIG. 6, the touch layer further includes a plurality of touch wires 8. The plurality of touch wires 8 includes a plurality of first touch wires 801 and a plurality of second touch wires 802. The touch display panel further includes a plurality of bonding electrodes 9.

One touch wire 8 of the touch wires 8 extends from one end of the first touch electrode 5 or the second touch electrode 6 through the peripheral region NA and is electrically connected with one bonding electrode 9 of the bonding electrodes 9.

In some embodiments, the touch wire further includes a metal grid structure formed by interweaving metal lines.

In some embodiments, the touch wire is located in at least one touch conductive layer.

In some embodiments, the touch wire is located in the first touch conductive layer or the second touch conductive layer.

Alternatively, in some embodiments, as shown in FIG. 7, the touch wire 8 includes a first sub-wire 8-1 located in the first touch conductive layer 201-1, and a second sub-wire 8-2 located in the second touch conductive layer 201-2. The second sub-wire 8-2 is electrically connected with the first sub-wire 8-1 through a through hole penetrating the touch insulating layer 202. That is, double-layer wiring of the touch wire can reduce impedance of the touch wire by connecting the first sub-wire and the second sub-wire in parallel.

A display apparatus according to an embodiment of the present disclosure includes the touch display panel according to an embodiment of the present disclosure.

The display apparatus according to an embodiment of the present disclosure is any product or component with display function such as a mobile phone, a tablet computer, a television, a display, a notebook computer, a digital photo frame, a navigator. Other essential components of the display apparatus are as will be understood by those skilled in the art, and are not intended to be exhaustive or to be limiting of the present disclosure. For the implementation of the display apparatus, reference may be made to above embodiments of the touch display panel, and the repetition thereof is omitted.

To sum up, for the touch display panel according to an embodiment of the present disclosure, in a case of h1>2.5, the line width h1 of the metal line included in the touch layer and the size h2 of the touch display panel satisfy 1.5≤h2/h1≤3.6. The larger the size h2 of the touch display panel is, the larger the line width h1 of the metal line is. Therefore, with the increase of the size of the touch display panel, the resistance of the touch conductive layer is reduced by correspondingly increasing the line width of the metal line, reducing the RC Loading. Then the signal attenuation is reduced when using the active stylus for touch control, to improve the signal-to-noise ratio, Hover touch, linearity and accuracy of the active stylus. In addition, h2/h1≤3.6 prevents the increase in the line width from failing to satisfy the RC Loading required for the size of the touch display panel in the case where h2/h1 exceeds 3.6. 1.5≤h2/h1 can prevent the metal line from being too wide to shield an opening region of the display substrate, and prevent a light-emitting rate of the touch display panel from being affected.

Although embodiments of the present disclosure have been described, those of skill in the art may otherwise make various modifications and variations to these embodiments once they are aware of the basic inventive concept. Therefore, the claims intend to include embodiments as well as all these modifications and variations falling within the scope of the present disclosure.

Apparently, those skilled in the art can make various modifications and variations to embodiments of the present disclosure without departing from the spirit and scope of embodiments of the present disclosure. In this way, if the modifications and variations of embodiments of the present disclosure fall within the scope of the claims of the present disclosure and their equivalent technologies, the present disclosure is also intended to include these modifications and variations.

1. A touch display panel, comprising:
a display substrate; and
a touch layer, located at a display side of the display substrate and comprising a plurality of touch conductive layers; wherein one touch conductive layer of the touch conductive layers comprises a metal grid structure formed by interweaving a plurality of metal lines; wherein a line width h1 of one metal line of the metal lines and a size h2 of the touch display panel satisfy h1>2.5, 1.5≤h2/h1≤3.6, a unit of the line width h1 of the metal line is micrometer, and a unit of the size h2 of the touch display panel is inch.

2. The touch display panel according to claim 1, wherein the size of the touch display panel is less than 10 inches, and the line width of the metal line is less than or equal to 4 micrometers.

3. The touch display panel according to claim 1, wherein the size of the touch display panel is greater than or equal to 10 inches, and the line width of the metal line is greater than or equal to 5 micrometers and less than or equal to 6.5 micrometers.

4. The touch display panel according to claim 1, wherein the plurality of touch conductive layers comprise a first touch conductive layer and a second touch conductive layer at a side of the first touch conductive layer away from an encapsulation layer; the touch layer further comprises a touch insulating layer located between the first touch conductive layer and the second touch conductive layer;
a thickness of the first touch conductive layer is greater than or equal to 0.34 micrometers, and a thickness of the second touch conductive layer is greater than or equal to 0.42 micrometers.

5. The touch display panel according to claim 4, wherein the touch insulating layer is an inorganic touch insulating layer;
the thickness of the first touch conductive layer is less than or equal to 0.42 micrometers, a thickness of the inorganic touch insulating layer is greater than or equal to 0.35 micrometers and less than or equal to 0.43 micrometers, and the thickness of the second touch conductive layer is less than or equal to 0.5 micrometer.

6. The touch display panel according to claim 4, wherein the touch insulating layer is an organic touch insulating layer;
the thickness of the first touch conductive layer is less than or equal to 0.72 micrometers, a thickness of the organic touch insulating layer is greater than or equal to 1.4 micrometers and less than or equal to 1.8 micrometers, and the thickness of the second touch conductive layer is less than or equal to 0.72 micrometers.

7. The touch display panel according to claim 4, wherein the thickness of the first touch conductive layer is equal to the thickness of the second touch conductive layer.

8. The touch display panel according to claim 1, wherein the touch display panel comprises a display region and a peripheral region surrounding the display region; the display substrate comprises:
a base substrate;
a pixel defining layer, located at a side of the base substrate and comprising a plurality of opening regions; and
an encapsulation layer, comprising at least one organic encapsulation layer at a side of the pixel defining layer away from the base substrate; wherein in the display region, a difference between a minimum thickness of the organic encapsulation layer comprised in the encapsulation layer in a direction perpendicular to the base substrate and the size h2 of the touch display panel is greater than or equal to 1 micrometer; wherein in the display region, the minimum thickness of the organic encapsulation layer comprised in the encapsulation layer in the direction perpendicular to the base substrate is a thickness of the organic encapsulation layer corresponding to a position where the pixel defining layer is located in the direction perpendicular to the base substrate.

9. The touch display panel according to claim 8, wherein the size of the touch display panel is greater than 10 inches; the encapsulation layer further comprises: a first inorganic encapsulation layer, and a second inorganic encapsulation layer located at a side of the first inorganic encapsulation layer away from the base substrate; the at least one organic encapsulation layer comprises: a first inorganic encapsulation layer located between the first inorganic encapsulation layer and the second inorganic encapsulation layer;
in the display region, a minimum thickness h3 of the first organic encapsulating layer in the direction perpendicular to the base substrate is greater than or equal to 14 micrometers and less than or equal to 18 micrometers.

10. The touch display panel according to claim 9, wherein in the display region, a difference between the minimum thickness h3 of the first organic encapsulation layer in the direction perpendicular to the base substrate and the size h2 of the touch display panel is equal to 1 micrometer.

11. The touch display panel according to claim 8, wherein the encapsulation layer further comprises: a first inorganic encapsulation layer, and a second inorganic encapsulation layer located at a side of the first inorganic encapsulation layer away from the base substrate; the at least one organic encapsulation layer comprises: a first inorganic encapsulation layer located between the first inorganic encapsulation layer and the second inorganic encapsulation layer, and a second inorganic encapsulation layer located at a side of the second inorganic encapsulation layer away from the first organic encapsulation layer.

12. The touch display panel according to claim 11, wherein a minimum thickness of the second organic encapsulation layer in the display region is less than a minimum thickness of the first organic encapsulation layer in the display region.

13. The touch display panel according to claim 12, wherein the size of the touch display panel is greater than 10 inches; the minimum thickness of the first organic encapsulating layer in the display region is greater than or equal to 12 micrometers and less than or equal to 18 micrometers, the minimum thickness of the second organic encapsulating layer in the display region is greater than or equal to 8 micrometers and less than or equal to 14 micrometers.

14. A touch display panel, comprising a display region and a peripheral region surrounding the display region; wherein the touch display panel comprises:
a display substrate, comprising a base substrate, a pixel defining layer and an encapsulation layer, wherein the pixel defining layer and the encapsulation layer are located at a side of the base substrate; the pixel defining layer comprises a plurality of opening regions, the encapsulation layer comprises at least one organic encapsulation layer at a side of the pixel defining layer away from the base substrate; in the display region, a difference between a minimum thickness of the organic encapsulation layer comprised in the encapsulation layer in a direction perpendicular to the base substrate and a size h2 of the touch display panel is greater than or equal to 1 micrometer; wherein in the display region, the minimum thickness of the organic encapsulation layer comprised in the encapsulation layer in the direction perpendicular to the base substrate is a thickness of the organic encapsulation layer corresponding to a position where the pixel defining layer is located in the direction perpendicular to the base substrate; and
a touch layer, located at a display side of the display substrate.

15. The touch display panel according to claim 14, wherein the size of the touch display panel is greater than 10 inches; the encapsulation layer further comprises a first inorganic encapsulation layer, and a second inorganic encapsulation layer located at a side of the first inorganic encapsulation layer away from the base substrate; the at least one organic encapsulation layer comprises: a first inorganic encapsulation layer located between the first inorganic encapsulation layer and the second inorganic encapsulation layer;
in the display region, a minimum thickness h3 of the first organic encapsulating layer in the direction perpendicular to the base substrate is greater than or equal to 14 micrometers and less than or equal to 18 micrometers.

16. The touch display panel according to claim 15, wherein in the display region, a difference between the minimum thickness h3 of the first organic encapsulation layer in the direction perpendicular to the base substrate and the size h2 of the touch display panel is equal to 1 micrometer.

17. The touch display panel according to claim 14, wherein the encapsulation layer further comprises: a first inorganic encapsulation layer, and a second inorganic encapsulation layer located at a side of the first inorganic encapsulation layer away from the base substrate; the at least one organic encapsulation layer comprises: a first inorganic encapsulation layer located between the first inorganic encapsulation layer and the second inorganic encapsulation layer, and a second inorganic encapsulation layer located at a side of the second inorganic encapsulation layer away from the first organic encapsulation layer.

18. The touch display panel according to claim 17, wherein a minimum thickness of the second organic encapsulation layer in the display region is less than a minimum thickness of the first organic encapsulation layer in the display region.

19. The touch display panel according to claim 18, wherein the size of the touch display panel is greater than 10 inches; the minimum thickness of the first organic encapsulating layer in the display region is greater than or equal to 12 micrometers and less than or equal to 18 micrometers, the minimum thickness of the second organic encapsulating layer in the display region is greater than or equal to 8 micrometers and less than or equal to 14 micrometers.

20. A display apparatus, comprising the touch display panel according to claim 1.
